(19) United States
(12) Patent Application Publication
(10) Pub. No.: US 2010/0092665 A1
(43) Pub. Date: Apr. 15, 2010

(54) EVAPORATING APPARATUS, APPARATUS FOR CONTROLLING EVAPORATING APPARATUS, METHOD FOR CONTROLLING EVAPORATING APPARATUS AND METHOD FOR USING EVAPORATING APPARATUS

(75) Inventor: Kenji Sudou, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/442,973

(22) PCT Filed: Sep. 25, 2007
(86) PCT No.: PCT/JP2007/068567

§ 371 Date: Mar. 26, 2009

(30) Foreign Application Priority Data
Sep. 27, 2006 (JP) 2006-262008

(51) Int. Cl. C23C 16/52; C23C 16/00

(52) U.S. Cl. 427/248.1; 118/726; 118/667

(57) ABSTRACT

An evaporating apparatus includes a first processing chamber and a second processing chamber, and a blowing device accommodated in the first processing chamber and a vapor deposition source accommodated in the second processing chamber are connected with each other via a connection pipe. An exhaust mechanism for evacuating the inside of the first processing chamber to a preset vacuum level is connected with the first processing chamber. Organic molecules vaporized from the vapor deposition source are blown out from the blowing device via the connection pipe and is adhered on a substrate, whereby a thin film is formed on the substrate. By installing the first processing chamber and the second processing chamber separately, the first processing chamber is not opened to the atmosphere when a film forming material is replenished, so that exhaust efficiency can be improved.

### TECHNICAL FIELD

The present invention relates to an evaporating apparatus, an apparatus for controlling the evaporating apparatus, a method for controlling the evaporating apparatus and a method for using the evaporating apparatus. More particularly, the present invention relates to an evaporating apparatus featuring high exhaust efficiency and a control method therefor.

### BACKGROUND ART

Widely employed in a manufacturing process of an electronic device such as a flat panel display or the like is an evaporating method for forming a film on a target object by adhering gas molecules, which is generated as a result of vaporizing a preset film forming material, to the target object. Among various types of devices manufactured by using such evaporating technology, an organic EL display is particularly known to be superior to a liquid crystal display for the reason of its self-luminescence, high reaction speed, low power consumption and so forth. Accordingly, an increasing demand for the organic EL display is expected from now on, and, particularly, it is attracting high attention in the field of manufacture of the flat display panel which is expected to be scaled-up. Thus, the evaporating technology employed in the manufacture of the organic EL display is deemed to be very important.

The evaporating technology getting attention under such technical background is implemented by an evaporating apparatus. Conventionally, in the evaporating apparatus, a vapor deposition source for vaporizing the film forming material and a blowing mechanism for blowing out the vaporized organic molecules toward the target object has been accommodated in a single vessel. Accordingly, a series of film forming processes involving the steps of vaporizing the film forming material contained in the vapor deposition source; and adhering the vaporized film forming material to the target object by blowing out it from the blowing mechanism have been performed within the same vessel (see, for example, Patent Document 1).

In the above-stated series of film forming processes, however, the inside of the vessel needs to be maintained at a preset vacuum level. To elaborate, the temperature of the vapor deposition sources increases up to about 200° C. to 500° C. to vaporize the film forming material therein. Thus, if the film forming process is performed in the atmosphere, the molecules of the film forming material would repetitively collide with residual gas molecules inside the vessel before they reach the target object, whereby the high-temperature heat generated from the vapor deposition source would be transferred to parts, e.g., various sensors inside a processing chamber, resulting in deterioration of characteristics of each part or damage of the part itself.

In contrast, if the film forming process is performed while the inside of the vessel is kept at the preset vacuum level, the possibility of the collision of the molecules of the film forming material with the residual gas molecules inside the vessel prior to their arrival at the target object becomes very low, so that the transfer of the heat generated from the vapor deposition source to other parts inside the processing chamber can be suppressed (i.e., heat insulation by vacuum is achieved). Thus, the temperature inside the vessel can be controlled with high accuracy, and the controllability of the film formation can be improved. As a result, a uniform film of a fine quality can be formed on the target object.

Patent Document 1: Japanese Patent Laid-open Publication No. 2000-282219

### DISCLOSURE OF THE INVENTION

### Problems to be Solved by the Invention

However, during the film formation, the film forming material stored in the vapor deposition source is consumed all the time as it is vaporized and blowing out from the blowing mechanism. Thus, the vapor deposition source needs to be replenished with the film forming material whenever necessary. Conventionally, the inside of the vessel must be opened to the atmosphere and the power of an exhaust system needs to be turned off every time the supplement is made. Thus, a great amount of energy is necessitated whenever the power of the exhaust system is turned on again after the supplement of the source material is completed.

Furthermore, whenever the inside of the vessel is opened to the atmosphere to supplement the source material into the vapor deposition source, the vacuum level inside the vessel decreases. Thus, the time period necessary to depressurize the inside of the vessel to the preset vacuum level again after the supplement of the source material becomes longer than that in case that the inside of the vessel is always maintained at the preset vacuum level without being opened to the atmosphere. As a result, the supplement of the source material has been a cause of deterioration of the exhaust efficiency in that it consumes both the energy for re-driving the exhaust system and the energy for depressurizing the inside of the vessel to the preset vacuum level again after re-driving the exhaust system. Further, since the supplement of the source material has increased the time for re-setting the inside of the vessel to the preset vacuum level, reduction of throughput has been caused, resulting in deterioration of productivity.

### Means for Solving the Problems

In view of the foregoing, the present invention provides a novel and advanced evaporating apparatus having good exhaust efficiency, and an apparatus and method for controlling the evaporating apparatus.

In accordance with one aspect of the present invention, there is provided an evaporating apparatus for performing a film formation on a target object by vapor deposition, the apparatus including: a vapor deposition source for vaporizing a film forming material which is a source material for the film formation; a blowing mechanism connected with the vapor deposition source through a connection path, for blowing out the film forming material vaporized from the vapor deposition source; a first processing chamber accommodating the blowing mechanism therein, for performing therein the film formation on the target object with the film forming material blown out from the blowing mechanism; a second processing chamber installed separately from the first processing chamber, for accommodating the vapor deposition source therein; and an exhaust mechanism connected with the first processing chamber, for evacuating the inside of the first processing chamber to a preset vacuum level.

Here, the term “vaporization” or “evaporation” implies not only the phenomenon that a liquid is converted into a gas but also a phenomenon that a solid is directly converted into a gas without becoming a liquid (i.e., sublimation).

In the above-described configuration, the second processing chamber accommodating the vapor deposition source therein is installed separately from the first processing chamber in which the film forming process is performed on the target object. Thus, only the second processing chamber needs to be opened to the atmosphere when the film forming material is supplemented without having to open the first processing chamber to the atmosphere. Accordingly, the energy inputted from a power supply after the supplement of the film forming material can be reduced in comparison with conventional cases. As a result, exhaust efficiency can be improved.

Further, since the first processing chamber is not opened to the atmosphere even when the film forming material is supplemented, the time taken to depressurize the inside of the chamber to the preset vacuum level can be shortened in comparison with the conventional cases where the entire chamber is opened to the atmosphere. In consequence, the throughput can be improved, resulting in enhancement of the productivity.

The exhaust mechanism may be connected with the second processing chamber and may evacuate the inside of the second processing chamber to a predetermined vacuum level. With this configuration, by depressurizing the inside of the second processing chamber to a desired vacuum level, it is possible to reduce the possibility that the vaporized film forming material (gas molecules) collides with residual gas molecules inside the chamber before they reach the target object. Accordingly, high-temperature heat generated from the vapor deposition source is hardly transferred to other parts inside a processing chamber. Due to such heat insulation effect by vacuum, the internal temperature of the second processing chamber can be controlled with high accuracy, so that controllability of the film formation can be improved, and uniformity and characteristics of a film can be improved. Moreover, deterioration of characteristics of such parts as various sensors inside the second processing chamber or damage of the parts themselves that might be caused by the transfer of the high-temperature heat generated from the vapor deposition source to the parts can be avoided. Furthermore, the use of a heat insulator in the second processing chamber becomes unnecessary.

The vapor deposition source may be installed such that only the vicinity of its film forming material accommodating portion is in contact with a wall surface of the second processing chamber. As described above, when the inside of the second processing chamber is in the vacuum state, the heat insulation effect by vacuum is obtained inside the chamber. Accordingly, the heat inside the second processing chamber is discharged out to the atmosphere outside the second processing chamber via the wall surface of the second processing chamber from the vapor deposition source's portion in contact with the wall surface of the second processing chamber. As a result, the temperature of the vapor deposition source's portions other than its film forming material accommodating portion can be made to be higher than or equal to the temperature of the vicinity of the film forming material accommodating portion.

The second processing chamber may be provided with at least one of a prominent portion and a recess portion in the wall surface in contact with the vapor deposition source. With this configuration, the heat can be discharged out of the second processing chamber more easily.

Here, according to the disclosure of a book titled “Thin Film Optics” (published by Murata Seishiro, Maruzen Inc., 1^{st} edition on Mar. 15, 2003 and 2^{nd} edition on Apr. 10, 2004), vaporized molecules (gas molecules of the film forming materials) that have reached the substrate are not adhered to the substrate and accumulated thereon just as they are in a manner that they are fallen and stacked to form a film, but a part of them is reflected and rebounded into the vacuum. Further, some of the molecules adhered on the surface of the substrate keep moving on the surface; some of them are bound again into the vacuum; and some of them are caught in sites on the substrate to form a film. An average time of the molecules kept in adsorption state (average residence time τ) is indicated by an equation of τ=τ₀exp (Ea/kT), wherein Ea represents an activation energy for the escape.

Since T is an absolute temperature; k, a Boltzmann constant; and τ₀, a predetermined constant, the average residence time τ is deemed to be a function of the absolute temperature T. This equation indicates that the number of the gas molecules physically adhered to a transport path decreases with the increase of the temperature.

As stated above, by setting the temperature of the vapor deposition source's other portions to be higher than or equal to the temperature of the vicinity of the vapor deposition source's portion where the film forming material is accommodated, the possibility of the adherence of the film forming material to the vapor deposition source or a connection path can be reduced. Accordingly, a greater amount of gas molecules can be blown out from the blowing mechanism and adhered to the target object. As a consequence, utilization efficiency of material can be improved, resulting in reduction of manufacturing cost. Furthermore, by reducing the number of the gas molecules adhered to the vapor deposition source or the connection path, a cleaning cycle for the elimination of the deposits adhered to the vapor deposition source or the connection path can be lengthened. Consequently, throughput can be enhanced, and productivity can be improved.

The vapor deposition source may include a temperature control mechanism for controlling a temperature of the vapor deposition source. In this configuration, the temperature of the vapor deposition source can be controlled by using the temperature control mechanism installed at the vapor deposition source so as to further reduce the number of the gas molecules adhered to the vapor deposition source or the connection path while the film forming materials are being flown toward the blowing mechanism. As a result, the material utilization efficiency can be further improved.

Specifically, the temperature control mechanism may include a first temperature control mechanism and a second temperature control mechanism, the first temperature control mechanism may be disposed on the side of the film forming material accommodating portion of the vapor deposition source, so as to maintain a temperature of the film forming material accommodating portion to a predetermined temperature, and the second temperature control mechanism may be disposed at a vapor deposition source's outlet portion, from which the film forming material is discharged, so as to maintain a temperature of the outlet portion to be higher than or equal to the temperature of the film forming material accommodating portion.

An example of the first temperature control mechanism installed at the vapor deposition source's film forming material accommodating portion may be a first heater buried in a bottom wall of the vapor deposition source where the film forming material is stored (see, for example, 400e1 in FIG. 3). Further, an example of the second temperature control mechanism installed on the vapor deposition source's outlet side from which the film forming material is discharged may be a second heater (see, for example, 410e1 in FIG. 3) buried in the sidewall of the vapor deposition source. As an example of a temperature control using the first and second heaters, a voltage applied to the second heater from a power supply may be set to be higher than that applied to the first heater. In this way, the temperature of the vicinity (indicated by r in FIG. 3) of an outlet of each crucible from which the vaporized film forming material is blown out can be increased higher than the temperature of the vicinity of the vapor deposition source's film forming material accommodating portion (indicated by q in FIG. 3).

The temperature control mechanism may include a third temperature control mechanism, and the third temperature control mechanism may be disposed in the vicinity of the film forming material accommodating portion of the vapor deposition source so as to cool the film forming material accommodating portion.

During the film formation, the temperature of the vapor deposition source increases up to a high temperature level of about 200 to 500° C. Thus, when the vapor deposition source needs to be cooled first so as to supplement the film forming material, about half a day has been taken to cool the conventional vapor deposition source down to a temperature level where the supplement of the source material is possible. However, by cooling the vapor deposition source through the use of the third temperature control mechanism, maintenance time necessary for the supplement of the film forming material can be shortened.

As an example of the third temperature control mechanism, a coolant supply source for blowing out a coolant such as air can be used, for instance (see, for example, FIG. 7). As an example of a temperature control using the coolant supply source, the air supplied from the coolant supply source may be blown to the vicinity of the portion where the film forming material is accommodated. Accordingly, the film forming material accommodating portion can be cooled by the air.

More than one vapor deposition source may be installed, and a plurality of first sensors corresponding to the vapor deposition sources may be disposed in the inside of the second processing chamber to detect respective vaporization rates of film forming materials accommodated in the vapor deposition sources.

Conventionally, the vapor deposition sources and the blowing mechanism have been accommodated in the same chamber. Therefore, though the film forming rate of a mixture of film forming materials (i.e., a generation rate of a mixture of gas molecules) passing through the blowing mechanism could be detected, it was impossible to detect the vaporization rate of each film forming material (simple substance) vaporized from each vapor deposition source (i.e., a generation rate of gas molecules of each film forming material of simple substance) accurately.

However, in the evaporating apparatus in accordance with the present invention, the vapor deposition sources and the blowing mechanism are accommodated in the separate chambers. In this configuration, by using the plurality of first sensors installed inside the second processing chamber to correspond to the plurality of vapor deposition sources, the film forming rate of each film forming material contained in each vapor deposition source can be detected by using each first sensor.

Accordingly, the temperature of each vapor deposition source can be controlled with high accuracy based on the vaporization rate of each film forming material (simple substance) outputted from each sensor. As a result, by allowing the vaporization rate of the film forming material contained in each vapor deposition source to be approximate to a target value more accurately, a mixture ratio of the mixture of gas molecules blown out from the blowing mechanism can be controlled with higher accuracy. As a consequence, controllability of film formation can be improved, and more uniform thin film having better characteristics can be formed on the target object.

To control a temperature of each vapor deposition source based on the vaporization rate of each film forming material (simple substance) outputted from each sensor, a QCM (Quartz Crystal Microbalance) is used, for example. Below, the simple principle of the QCM will be explained.

In case that a density, an elastic modulus, a size or the like of a quartz vibrator body are varied equivalently by adhering a substance to the surface of a quartz vibrator, there occurs a variation of an electrical resonance frequency f, which is indicated by the following equation, due to the piezoelectric property of the vibrator.

f=½t(√C/ρ)

(t: thickness of a quartz piece, C: elastic constant, ρ: density)

By using this phenomenon, an infinitesimal quantity of deposits is measured quantitatively based on the variation of the resonance frequency of the quartz vibrator. A general term for the quartz vibrator designed as described is QCM. As can be seen from the equation, a change of the frequency is deemed to be determined based on a change of the elastic constant dependent on the adhered substance; and a thickness dimension of the adhered substance calculated in terms of the quartz density. Thus, the change of the frequency can be calculated in terms of the weight of the deposits.

A second sensor corresponding to the blowing mechanism may be additionally disposed in the inside of the first processing chamber to detect a film forming rate of the film forming material blown out from the blowing mechanism.

With this configuration, it is possible to detect the film forming rate of the mixture of film forming materials passing through the blowing mechanism by using the second sensor while concurrently detecting the vaporization rate of each film forming material (simple substance) contained in each vapor deposition source by using the first sensors. Accordingly, it is possible to measure the loss amount of the gas molecules of each film forming material as a result of their adherence to the connection path or the like while they are travelling from the vapor deposition source to the blowing mechanism through the connection path or the like. Thus, the temperature of each vapor deposition source can be controlled more accurately based on the vaporization rates of various kinds of film forming materials and the film forming rate of the mixture of film forming materials. Accordingly, the controllability of the film formation can be improved, and more uniform thin film having better characteristics can be formed on the target object. Further, as long as the first sensors are provided, installation of the second sensor is optional.

More than one vapor deposition source may be installed; different kinds of film forming materials may be accommodated in the vapor deposition sources, respectively; connection paths respectively connected with the vapor deposition sources may be coupled at a preset junction position; and based on the amounts of the different kinds of film forming materials vaporized from the vapor deposition sources per unit time, a flow path adjusting member may be installed at one of the connection paths upstream of the preset junction position to control a flow path of one connection path.

For example, based on the amounts of the different kinds of film forming materials vaporized from the vapor deposition sources per unit time, the flow path adjusting member may be installed at the connection path through which the film forming material having a low vaporization rate per unit time passes.

In case that the connection paths have same diameters, the internal pressure of a connection path through which a film forming material having a high vaporization rate per unit time passes after vaporized from the vapor deposition source becomes higher than the internal pressure of a connection path through which the film forming material having a low vaporization rate per the unit time passes. Accordingly, gas molecules tend to be introduced into the connection path having the lower internal pressure from the connection path having the higher internal pressure.

However, in accordance with the present invention, the flow path adjusting member is installed at the connection path through which the film forming material having the low vaporization rate per the unit time passes, based on the amounts of the different kinds of film forming materials evaporated from the plurality of vapor deposition sources per unit time. For example, when an orifice (partition plate) having a central hole is used as the flow path adjusting member, the flow path is narrowed at a portion where the orifice is installed, so that a passage of the gas molecules is restricted.

Accordingly, the gas molecules of the film forming material can be prevented from being introduced from the connection path with the higher internal pressure into the connection path with the low internal pressure. Thus, by preventing the backflow of the gas molecules of respective film forming materials, they can be sent to the blowing mechanism. As a result, a greater amount of gas molecules can be deposited to the target object, resulting in improvement of the utilization efficiency of material.

The flow path adjusting member may be installed at one of exhaust paths for exhausting a part of each vaporized film forming material toward the first sensors and the second sensor to control a flow path of one exhaust path.

In this configuration, the amount of the gas molecules of the film forming materials blown out toward the first sensor and the second sensor can be restricted by using the flow path adjusting member. Accordingly, unnecessary exhaust of the gas molecules of the film forming materials can be suppressed, so that the utilization efficiency of material can be further improved.

More than one blowing mechanism may be installed, and the first processing chamber may accommodate the blowing mechanisms therein, and a plurality of film forming processes may be consecutively performed on the target object with the film forming material blown out from each blowing mechanism in the first processing chamber.

In accordance with the present invention, a plurality of films is consecutively formed within the same processing chamber. Thus, the throughput can be enhanced and the productivity can be improved. Furthermore, since a plurality of processing chambers needs not to be installed separately for each of the films to be formed as in a conventional case, the scale-up of the equipment is suppressed, and cost therefor can be reduced.

The first processing chamber may form an organic EL film or an organic metal film on the target object by vapor deposition by using an organic EL film forming material or an organic metal film forming material as a source material.

In accordance with another aspect of the present invention, there is provided a control apparatus for controlling the evaporating apparatus for feedback controlling a temperature of a temperature control mechanism installed at each vapor deposition source based on the respective vaporization rates of the film forming materials detected by the first sensors.

By using this control apparatus, the temperature of each vapor deposition source can be controlled with high accuracy in real time, based on the vaporization rates of the different kinds of film forming materials (simple substances) detected by respective first sensors. As a result, by allowing the vaporization rate of the film forming material contained in each vapor deposition source to be approximate to a target value more accurately, the mixture ratio of the mixture of gas molecules blown out from the blowing mechanism can be controlled with higher accuracy. As a consequence, the controllability of film formation can be improved, and more uniform thin film having better characteristics can be formed on the target object.

Further, in accordance with still another aspect of the present invention, there is provided a control apparatus for controlling the evaporating apparatus for feedback controlling a temperature of a temperature control mechanism installed at each vapor deposition source based on the respective vaporization rates of the film forming materials detected by the first sensors and the film forming rate of the film forming material detected by the second sensor.

By using this control apparatus, the temperature of each vapor deposition source can be more accurately controlled in real time, based on the vaporization rates of the different film forming materials (simple substance) detected by respective first sensors and the film forming rate of the mixture of the gas molecules detected by the second sensor. As a consequence, the controllability of film formation can be improved, and more uniform thin film having better characteristics can be formed on the target object.

At this time, the control apparatus of the evaporating apparatus may feedback control the temperature of the temperature control mechanism installed at each vapor deposition source such that a temperature of a vapor deposition source's outlet portion from which the film forming material is discharged is set to be higher than or equal to a temperature of a film forming material accommodating portion of the vapor deposition source.

As described above, an adhesion coefficient decreases with the increase of the temperature. Accordingly, by feedback controlling the temperature of the temperature control mechanism installed at every vapor deposition source such that the temperature of the vapor deposition source's outlet portion from which the film forming material is discharged is set to be higher than or equal to the temperature of the vicinity of the film forming material accommodating portion, the number of gas molecules adhered to the outlet portion of the vapor deposition source or the connection path can be reduced. As a result, a greater amount of gas molecules can be adhered to the target object. Thus, the utilization efficiency of material can be improved, resulting in reduction of manufacturing cost. Furthermore, a cleaning cycle for the elimination of deposits adhered to the vapor deposition source or the connection path can be lengthened.

In accordance with still another aspect of the present invention, there is provided a control method for controlling the evaporating apparatus by which a temperature of a temperature control mechanism installed at each vapor deposition source is feedback controlled based on the respective vaporization rates of film forming materials detected by the first sensors.

In accordance with still another aspect of the present invention, there is provided a control method for controlling the evaporating apparatus by which a temperature of a temperature control mechanism installed at each vapor deposition source is feedback controlled based on the respective vaporization rates of the film forming materials detected by the first sensors and the film forming rate of the film forming material detected by the second sensor.

In accordance with these control methods, it is possible to control the temperature of each vapor deposition source based on the film forming rate outputted from each sensor with high accuracy. As a result, the controllability of the film formation can be further improved, and more uniform film having better characteristics can be formed on the target object.

In accordance with still another aspect of the present invention, there is provided a method for using the evaporating apparatus for vaporizing the film forming material accommodated in the vapor deposition source in the inside of the second processing chamber; blowing out the vaporized film forming material from the blowing mechanism through the connection path; and performing the film formation on the target object with the blown film forming material in the inside of the first processing chamber.

As stated so far, the present invention is capable of providing the novel and advanced evaporating apparatus having high exhaust efficiency; the control apparatus for the evaporating apparatus; the control method for the evaporating apparatus and the method for using the evaporating apparatus.

### BRIEF DESCRIPTION OF THE DRAWINGS

FIG. 1 provides a perspective view of major components of an evaporating apparatus in accordance with a first embodiment of the present invention and a modification example thereof;

FIG. 2 sets forth a cross sectional view of the evaporating apparatus in accordance with the first embodiment of the present invention taken along a line A-A of FIG. 1;

FIG. 3 presents an enlarged view showing a first crucible and its vicinities shown in FIG. 2;

FIG. 4 depicts a diagram for describing a film formed by a 6-layer consecutive film forming process in accordance with the first embodiment and the modification example thereof;

FIG. 5 offers a graph showing a relationship between temperature and adhesion coefficient; and

FIG. 6 illustrates a cross sectional view of an evaporating apparatus in accordance with the modification example of the first embodiment taken along the line A-A of FIG. 1.

### EXPLANATION OF CODES

10: Evaporating apparatus
100: First processing chamber
110: Blowing device
110e1: Blowing mechanism
110e11: Blowing portion
110e12: Frame
110e15: Orifice
110e2: Transport mechanism
110e21: Transport path
200: Second processing chamber
210: Vapor deposition source
210e1: First crucible
210e13: Orifice
210e2: Second crucible
210e23: Orifice
210e3: Third crucible
210e33: Orifice
220e: Connection pipe
230e: Valve
240e2, 240e3: Orifices
300, 310: QCMs
400e, 410e: Heaters
700: Controller

### BEST MODE FOR CARRYING OUT THE INVENTION

Hereinafter, embodiments of the present invention will be described in detail with reference to the accompanying drawings. Like reference numerals denote like parts through the whole document, and redundant description will be omitted.

### First Embodiment

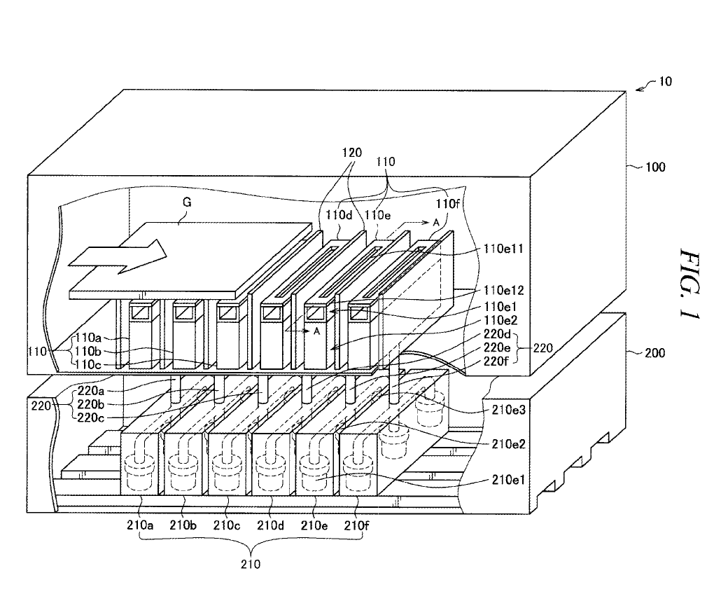

First, an evaporating apparatus in accordance with a first embodiment of the present invention will be described with reference to FIG. 1, which provides a perspective view showing major components of the evaporating apparatus. The following description is provided for the example case of manufacturing an organic EL display by consecutively depositing 6 layers including an organic EL layer in sequence on a glass substrate (hereinafter simply referred to as “substrate”) by using the evaporating apparatus in accordance with the first embodiment of the present invention.

(Evaporating Apparatus)

The evaporating apparatus 10 includes a first processing chamber 100 and a second processing chamber 200. Below, the shape and internal configuration of the first processing chamber 100 will be first explained, and the shape and internal configuration of the second processing chamber 200 will be described later.

The first processing chamber 100 has a rectangular parallelepiped shape and incorporates a first blowing device 110a, a second blowing device 110b, a third blowing device 110c, a fourth blowing device 110d, a fifth blowing device 110e and a sixth blowing device 110f. Inside the first processing chamber 100, film formation processes are consecutively performed on the substrate G by gas molecules blown out from the six blowing devices 110.

The six blowing devices 110 are arranged in parallel to each other at a same distance therebetween such that their lengthwise directions become substantially perpendicular to the advancing direction of the substrate G. Partition walls 120 are disposed between the respective blowing devices 110. By separating the blowing devices 110 with the seven partition walls 120, gas molecules of a film forming material blown out from each blowing device 110 can be prevented from being mixed with gas molecules blown out from adjacent blowing devices 110.

Each blowing device 110 has a length approximately equal to the width of the substrate G, and they have the same shape and configuration. Thus, the internal configuration of the fifth blowing device 110e will only be explained for example, while omitting description of the other blowing devices 110.

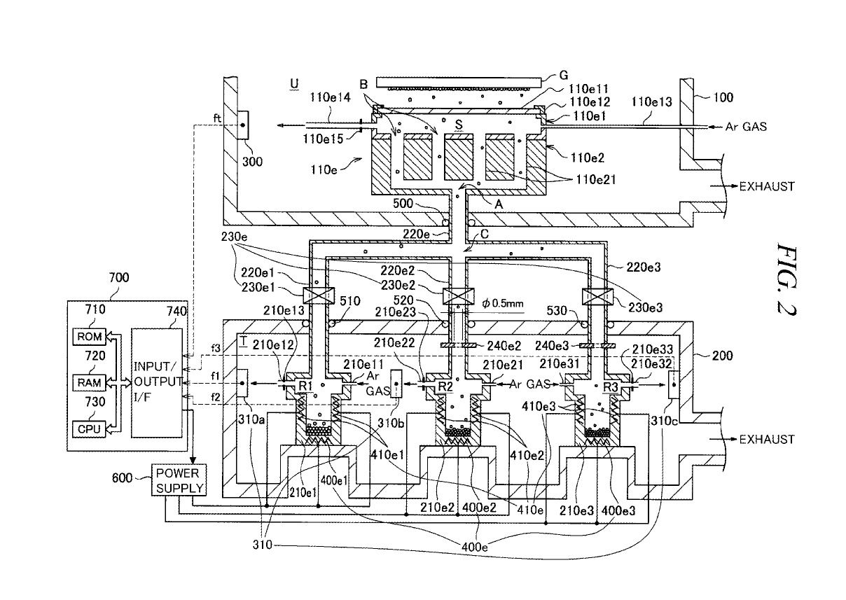

As can be seen from FIG. 1 and FIG. 2 which is a cross sectional view of the evaporating apparatus 10 taken along a line A-A of FIG. 1, the fifth blowing device 110e includes a blowing mechanism 110e1 in its upper portion and a transport mechanism 110e2 in its lower portion. The blowing mechanism 110e1, of which an inside S is hollow, has a blowing portion 110e11 and a frame 110e12 at its top portion.

The blowing portion 110e11 is provided with a central opening (see FIG. 1) communicating with the inside S, and a vaporized film forming material is blown out from the opening. The frame 110e12 is a frame body having the opening of the blowing portion 110e11 in its center portion and fixes the blowing portion 110e11 at its peripheral portion with screws.

The blowing mechanism 110e1 is provided with a supply pipe 110e13 inserted through the sidewalls of the first processing chamber 100 and the blowing mechanism 110e1 to thereby allow the exterior of the first processing chamber 100 and the inside S of the blowing mechanism 110e1 to communicate with each other. The supply pipe 110e13 is used to supply a nonreactive gas (e.g., an Ar gas) from a non-illustrated gas supply source into the inside S of the blowing mechanism 110e1. Though it is desirable to supply the nonreactive gas so as to improve the uniformity of the mixture of gas molecules (film forming gas) present in the inside S, it is not indispensable.

Further, the blowing mechanism 110e1 is also provided with an exhaust pipe 110e14 inserted through the sidewall of the blowing mechanism 110e1 to thereby allow the inside U of the first processing chamber 100 and the inside S of the blowing mechanism 110e1 to communicate with each other. Further, an orifice 110e15 is inserted in the exhaust pipe 110e14 to narrow the passageway.

The transport mechanism 110e2 has four transport paths 110e21 formed through the inside thereof after branched from one flow path. The distances from a branch portion A (inlet of the transport paths 110e21) to openings B of the four transport paths 110e21 (outlets of the transport paths 110e21) are almost same.

A QCM (Quartz Crystal Microbalance: quartz vibrator) 300 is installed in the vicinity of the opening of the exhaust pipe 110e14 inside the first processing chamber 100. The QCM 300 is an example of a second sensor for detecting a generation rate of the mixture of gas molecules exhausted from the opening of the exhaust pipe 110e14, that is, a film forming rate (D/R: deposition rate). Below, the principle of the QCM will be simply explained.

In case that a density, an elastic modulus, a size or the like of a quartz vibrator body are varied equivalently by adhering a substance to the surface of a quartz vibrator, there occurs a variation of an electrical resonance frequency f, which is indicated by the following equation, due to the piezoelectric property of the vibrator.

f=½t(√C/ρ)

(t: thickness of a quartz piece, C: elastic constant, ρ: density)

By using this phenomenon, an infinitesimal quantity of deposits is measured quantitatively based on the variation of the resonance frequency of the quartz vibrator. A general term for the quartz vibrator designed in this way is QCM. As can be seen from the equation, a change of the frequency is deemed to be determined based on a change of the elastic constant dependent on the adhered substance; and a thickness dimension of the adhered substance calculated in terms of the quartz density. Thus, the change of the frequency can be calculated in terms of the weight of the deposits.

By using such principle, the QCM 300 outputs a frequency signal ft for detecting a film thickness adhered on the quartz vibrator (film forming rate). The film forming rate detected from the frequency signal ft is used to feedback-control the temperature of each crucible so as to control the vaporization rate of each film forming material contained in the crucible.

(Second Processing Chamber)

Now, the shape and internal configuration of the second processing chamber 200 will be described with reference to FIGS. 1 and 2. The second processing chamber 200 is installed separately from the first processing chamber 200 as mentioned above, and has a substantially rectangular parallelepiped shape and also is provided with prominent portions and recess portions at its bottom portion. A relationship between these prominent portions and recess portions at the bottom portion and heat transfer will be explained later.

The second processing chamber 200 includes a first vapor deposition source 210a, a second vapor deposition source 210b, a third vapor deposition source 210c, a fourth vapor deposition source 210d, a fifth vapor deposition source 210e and a sixth vapor deposition source 210f.

The first to the sixth vapor deposition sources 210a to 210f are connected with the first to the sixth blowing devices 110a to 110f via connection pipes 220a to 220f, respectively.

Each vapor deposition source 210 has the same shape and configuration. Thus, the internal configuration of the fifth vapor deposition source 210e will only be explained for example with reference to FIGS. 1 and 2, while omitting description of the other vapor deposition sources 210.

The fifth vapor deposition source 210e includes a first crucible 210e1, a second crucible 210e2 and a third crucible 210e3 as three vapor deposition sources. The first crucible 210e1, the second crucible 210e2 and the third crucible 210e3 are connected with a first connection pipe 220e1, a second connection pipe 220e2 and a third connection pipe 220e3, respectively, and these three connection pipes 220e1 to 220e3 are coupled to each other at a junction portion C after penetrating the processing chamber 200 and connected to the fifth blowing device 110e after penetrating the processing chamber 100.

The crucibles 210e1 to 210e3 contain therein different kinds of film forming materials as a film-forming source material, and by setting the temperature of each crucible to a high temperature level of, e.g., about 200 to 500° C., the various kinds of film forming materials are vaporized.

Installed at the connection pipes 220e1 to 220e3 outside the second processing chamber (in the atmosphere) are valves 230e1 to 230e3, respectively. By manipulating the opening/closing of each valve 230e, it is controlled whether each film forming material (gas molecules) is supplied into the first processing chamber 100 or not. Further, when replenishing each crucible with the film-forming source material, not only the inside of the second processing chamber 200 but also the inside of the connection pipe 220e is opened to the atmosphere. Accordingly, by closing each valve 230e during the supplement of the film-forming source material, communication with the inside of the connection pipe 220e and the inside of the first processing chamber 100 is cut off, so that the inside of the first processing chamber 100 can be prevented from being opened to the atmosphere and thus the inside of the first processing chamber 100 can be maintained in a preset depressurized state.

Orifices 240e2 and 240e3 respectively provided with a hole having a diameter of about 0.5 mm are inserted in the second and third connection pipes 220e2 and 220e3, respectively, inside the second processing chamber.

Further, the connection pipe 220e (including the first connection pipe 220e1, the second connection pipe 220e2 and the third connection pipe 220e3) connects the vapor deposition source 210 with the blowing device 110, functioning as a connection path for transporting the film forming material vaporized from the vapor deposition source 210 toward the blowing device 110.

Supply pipes 210e11, 210e21, and 210e31 are installed at the crucibles 210e1, 210e2 and 210e3, respectively, in a manner that they are inserted through the sidewall of each crucible, thus allowing the inside T of the second processing chamber 200 to communicate with the insides R1, R2 and R3 of the crucibles. The supply pipes 210e11, 210e21 and 210e31 are used to supply a nonreactive gas (e.g., an Ar gas) into the inside of each crucible from a non-illustrated gas supply source. The supplied nonreactive gas functions as a carrier gas which carries each film-forming gas present in the insides R1, R2 and R3 to the blowing mechanism 110e1 through the connection pipe 220e and the transport path 110e21.

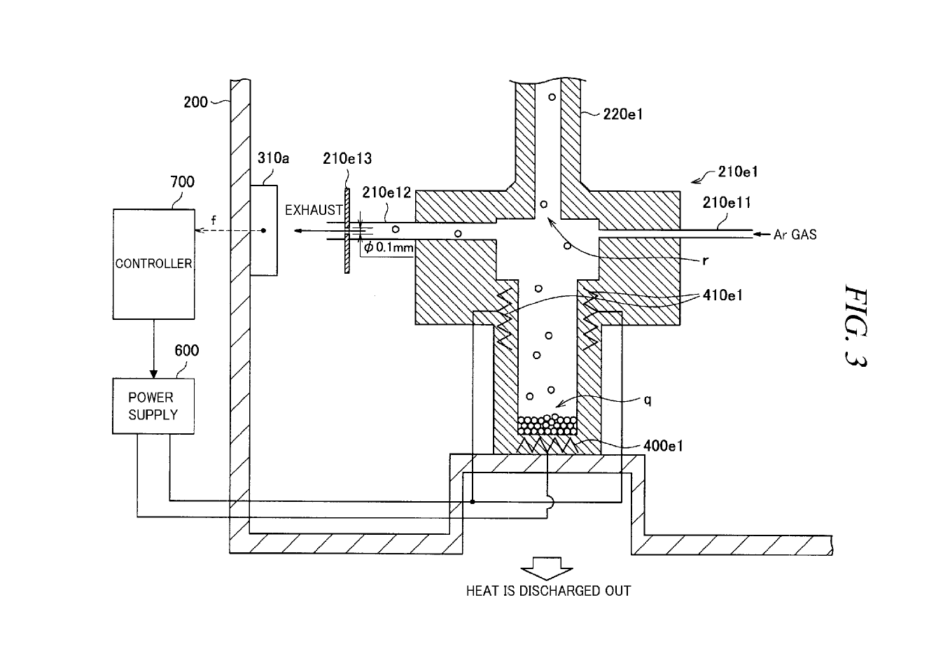

Further, exhaust pipes 210e12, 210e22 and 210e32 are installed at the crucibles 210e1, 210e2 and 210e3, respectively, in a manner that they are inserted through the sidewall of each crucible 210e, thus allowing the inside T of the processing chamber 200 to communicate with the insides R1, R2 and R3 of each crucible 210e. Orifices 210e13, 210e23 and 210e33 are inserted in the exhaust pipes 210e12, 210e22, and 210e32, respectively. As shown in FIG. 3, each of the orifices 210e13 to 210e33 is provided with a central opening having a diameter of about 0.1 mm, and they function to narrow a passageway of the exhaust pipes 210e12 to 210e32.

In the inside T of the second processing chamber 200, QCMs 310a to 310c are installed in the vicinity of the exhaust pipes 210e12 to 210e32, respectively. The QCMs 310a to 310c output frequency signals f1 to f3 to detect the thickness (film forming rate) of films adhered to quartz vibrators after the gas molecules are exhausted from the openings of the exhaust pipes 210e12 to 210e32. The film forming rates thus calculated from the frequency signals f1 to f3 are used to feedback control the temperature of each crucible so as to control the vaporization rate of each film forming material contained in each crucible. The QCM 310 is an example of a first sensor.

Heaters 400 and 410 are embedded in each vapor deposition source 210e to control the temperature of the vapor deposition source 210e. For example, in the first crucible 210e1, a heater 400e1 is buried in its bottom wall and a heater 410e1 is installed in its sidewall. Likewise, in the second and third crucibles 210e2 and 210e3, heaters 400e2 and 400e3 are buried in their bottom walls and heaters 410e2 and 410e3 are installed in their sidewalls, respectively. Each of the heaters 400 and 410 is connected with an AC power supply 600.

A controller 700 includes a ROM 710, a RAM 720, a CPU 730 and an input/output interface (I/F) 740. The ROM 710 and the RAM 720 store therein, for example, data indicating a relationship between the frequency and the film thickness, programs for feedback controlling the heaters, or the like. By using such various data or programs stored in those storage areas, the CPU 730 calculates a generation rate of gas molecules of each film forming material from the frequency signals ft, f1, f2, f3 inputted from the input/output I/F; calculates a voltages to be applied to the heaters 400e1 to 400e3 and the heaters 410e1 to 410e3 based on the calculated generation rate; and transmit the results to the AC power supply 600 as temperature control signals. The AC power supply 600 applies a voltage to the respective heaters based on the temperature control signals transmitted from the controller 700.

An O-ring 500 is disposed at a bottom surface of the first processing chamber 100's outer wall through which the connection pipe 220e is inserted, whereby the communication between the atmosphere and the first processing chamber 100 is cut off, and thus the inside of the first processing chamber can be hermetically kept.

Further, O-rings 510 to 530 are installed at a top surface of the second processing chamber 200's outer wall through which the connection pipes 220e1 to 220e3 are inserted, respectively, whereby the communication between the atmosphere and the second processing chamber 200 is cut off, and the inside of the second processing chamber 200 can be hermetically kept. Moreover, the insides of the first and second processing chambers 100 and 200 can be depressurized to preset vacuum levels by a non-illustrated exhaust system.

The substrate G is electrostatically attracted and held on a stage (not shown) having a sliding mechanism in an upper region of the first processing chamber 100. As shown in FIG. 1, the substrate G is moved from the first blowing device 110a to the second blowing device 110b, the third blowing device 110c, the fourth blowing device 110d, the fifth blowing device 110e and to the six blowing device 110f (110a→110b→110c→110d→110e→110f) at a preset speed while being located slightly above each of the blowing devices 110a to 110f separated by the seven partition walls 120. As a result, different films are formed on the substrate G in six layers depending on the film forming materials blown out from the respective blowing devices 110a to 110f. Below, specific operation of the evaporating apparatus 10 during this 6-layer consecutive film forming process will be explained.

(6-Layer Consecutive Film Forming Process)

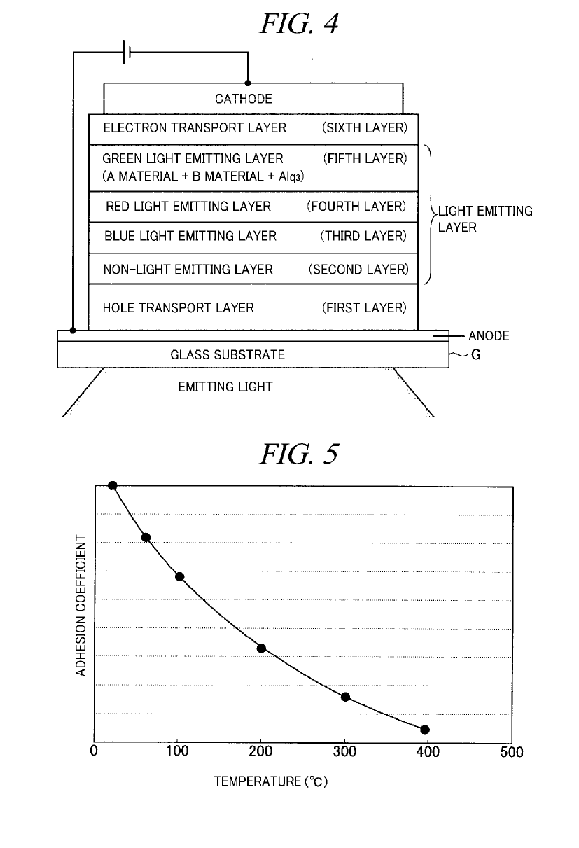

First, film forming materials used in the 6-layer consecutive film forming process will be described with reference to FIG. 4. FIG. 4 illustrates the state of each layer deposited on the substrate G as a result of performing the 6-layer consecutive film forming process by using the evaporating apparatus 10.

First, while the substrate G is being moved above the first blowing device 110a at a certain speed, a film forming material blown out from the first blowing device 110a is adhered to the substrate G, so that a hole transport layer as a first-layer is formed on the substrate G. Then, while the substrate G is being moved above the second blowing device 110b, a film forming material blown out from the second blowing device 110b is adhered to the substrate G, so that a non-light emitting layer (electron blocking layer) as a second-layer is formed on the substrate G. Likewise, while the substrate G is being moved above the third blowing device 110c, the fourth blowing device 110d, the fifth blowing device 110e and the six blowing device 110f (110c→110d→110e→110f) in this sequence, a blue light emitting layer as a third-layer, a red light emitting layer as a fourth-layer, a green light emitting layer as a fifth-layer and an electron transport layer as a sixth-layer are formed on the substrate G depending on film forming materials blown out from the blowing devices.

By the 6-layer consecutive film forming process of the evaporating apparatus 10 described above, the six films are consecutively formed within the same chamber (i.e., the first processing chamber 100). Accordingly, throughput can be improved, resulting in enhancement of productivity. Further, since conventional installation of a plurality of processing chambers for the different types of films to be formed becomes unnecessary, scale-up of the apparatus can be prevented, and cost can be reduced.

(Maintenance: Supplement of Material)

While the above-described film forming process is being performed, the inside of the first processing chamber 100 needs to be maintained at a desired vacuum level, as explained above. It is because keeping the inside of the first processing chamber 100 at a desired vacuum level allows obtaining a heat insulating effect by vacuum, thus enabling an accurate control of the internal temperature of the first processing chamber 100. As a result, controllability of the film formation is improved, so that multi-layered uniform thin films having fine qualities can be formed on the substrate G.

Meanwhile, while the 6-layer consecutive film forming process is being performed on the substrate G, the film forming material contained in each crucible is vaporized and converted into gas molecules and then kept consumed after sent to the blowing mechanism from the vapor deposition source. Thus, it is required to replenish each crucible with the film forming material whenever necessary.

However, if the inside of the chamber is opened to the atmosphere and the exhaust system, under operation to maintain the inside of the processing chamber at a preset vacuum level, is turned off whenever each vapor deposition source is the replenished with the film forming material, a great amount of energy is consumed every time the exhaust system is turned on again after the supplement of the film forming material, resulting in deterioration of exhaust efficiency.

Accordingly, in the evaporating apparatus 10 in accordance with the present embodiment, the second processing chamber 200 for accommodating the vapor deposition sources is installed separately from the first processing chamber 100 for performing the film forming process on the substrate G. Thus, when the supplement of the film forming material is performed, only the second processing chamber 200 needs to be opened to the atmosphere without having to open the first processing chamber 100 to the atmosphere. Therefore, the energy inputted from the power supply after the supplement of the material can be reduced in comparison with the conventionally required amount. As a result, the exhaust efficiency can be improved.

As stated, the first processing chamber 100 is not opened to the atmosphere when the film forming material is supplemented. Thus, in comparison with conventional cases where the entire chamber is opened to the atmosphere, the time required to depressurize the inside of the chamber to a preset vacuum level can be reduced. As a consequence, the throughput can be improved, resulting in enhancement of the productivity.

Moreover, the inside of the second processing chamber 200 is also evacuated to a predetermined vacuum level during the film forming process. By depressurizing the inside of the second processing chamber 200 to a predetermined vacuum level, a heat insulation effect by vacuum is obtained, so that the internal temperature of the second processing chamber 200 can be controlled with high accuracy. Thus, the controllability of the film formation can be improved, so that more uniform thin films having better qualities can be formed on the substrate G. Furthermore, deterioration of characteristics of each part inside the second processing chamber 200, e.g., various sensors therein or damage of the parts themselves due to the transfer of high-temperature heat generated from the vapor deposition sources can be avoided. Further, use of a heat insulating material in the second processing chamber 200 becomes unnecessary.

(Prominent Portions and Recess Portions of the Second Processing Chamber and Heat Transfer)

As mentioned above, the prominent portions and recess portions are provided at the bottom surface of the second processing chamber 200, and each crucible is disposed such that only its bottom surface (an example of the vicinity of the film forming material accommodating portion) is in contact with a recess portion of the bottom wall of the second processing chamber 200.

As stated above, when the inside of the second processing chamber 200 is in a vacuum state, the heat insulating effect by vacuum is obtained in the second processing chamber. Accordingly, the heat inside the chamber is discharged out to the atmosphere through the second processing chamber from the crucible 210e1's portion in contact with the bottom wall of the second processing chamber 200, as illustrated in FIG. 3, for example. In this way, the temperature of the vicinities of the respective crucibles 210e1 to 210e3's film forming material accommodating portions can be set to be lower than or equal to the other portions of the crucibles 210e1 to 210e3.

Here, according to the disclosure of a book titled “Thin Film Optics” (published by Murata Seishiro, Maruzen Inc., 1^{st} edition on Mar. 15, 2003 and 2^{nd} edition on Apr. 10, 2004), vaporized molecules (gas molecules of the film forming materials) that have reached the substrate are not adhered to the substrate and accumulated thereon just as they are in a manner that they are fallen and stacked to form a film, but a part of them is reflected and rebounded into the vacuum. Further, some of the molecules adhered on the surface of the substrate keep moving on its surface; some of them are bound again into the vacuum; and some of them are caught in sites on the substrate to form a film. An average time of the molecules kept in adsorption state (average residence time T) is expressed by an equation of τ=τ₀exp (Ea/kT), wherein Ea represents an activation energy for the escape.

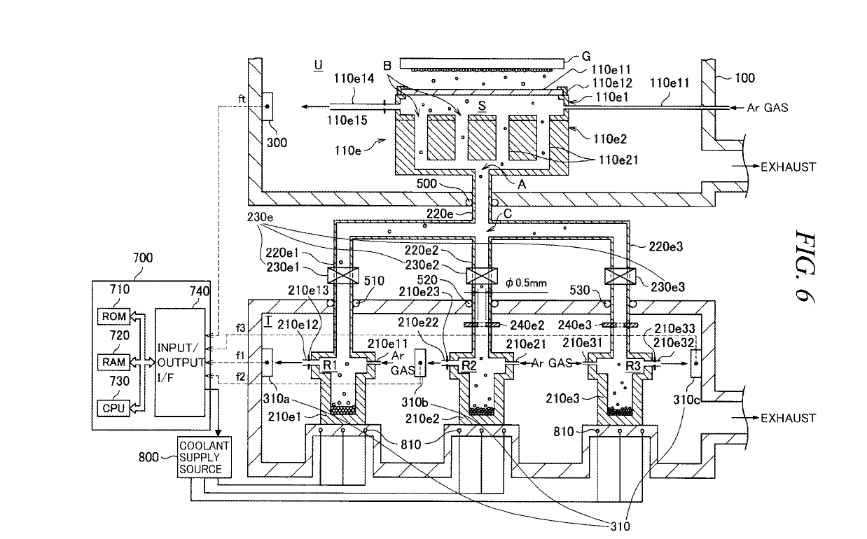

Since T is an absolute temperature; k, a Boltzmann constant; and τ₀, a predetermined constant, the average residence time τ is deemed to be a function of the absolute temperature T. The present inventors conducted calculations to investigate the relationship between temperature and adhesion coefficient. Here, α-NPD (diphenyl naphthyl diamine: an example of an organic material) was used as an organic material, and the calculation result is provided in FIG. 5. As can be seen from the result, it is found that the adhesion coefficient decreases with the increase of the temperature (° C.). That is, the result indicates that the number of gas molecules physically adhered to the transport path or the like decreases with the increase of the temperature.

As stated above, by setting the temperature of the vapor deposition source's portions other than where the film forming material is accommodated to be higher than or equal to the temperature of the vicinity of such film forming material accommodating portion, the number of the gas molecules adhered to the vapor deposition source 210, the connection pipe 220 or the transport path 110e21 can be reduced while the gas molecules are being flown toward the blowing device 110 after the film forming material is vaporized.

Accordingly, a greater amount of gas molecules can be blown out from the blowing device 110 and adhered to the substrate G. As a consequence, utilization efficiency of material can be improved, resulting in reduction of manufacturing cost. Furthermore, a cleaning cycle for the elimination of deposits adhered to the vapor deposition source 210 or the connection pipe 220 can be lengthened.

(Temperature Control Mechanism)

The evaporating apparatus 10 includes a temperature control mechanism for controlling a temperature of the vapor deposition source 210. As shown in FIG. 2, the vapor deposition source 210e includes the heaters 400e and 410e provided for each crucible therein. The heater 400e corresponds to a first temperature control mechanism disposed at each crucible's film forming material accommodating portion (marked by q in FIG. 3), and the heater 410e corresponds to a second temperature control mechanism disposed at each crucible's outlet side (marked by r in FIG. 3) from which the vaporized film forming material is discharged from each crucible.

In case that a voltage applied to the heater 410e from the AC power supply 600 is greater than or equal to that applied to the heater 400e, the temperature in the vicinity of the outlet of each crucible can be made higher than or equal to that of the vicinity of the film forming material accommodating portion.

In this way, by setting the temperature of the portion through which the film forming material passes to be higher than that of the portion where the film forming material is stored, the number of the gas molecules adhered to the vapor deposition source 210, the connection pipe 210 or the like can be further reduced. As a result, the utilization efficiency of material can be enhanced.

(Feedback Control by the Temperature Control Mechanism)

In the evaporating apparatus 10 in accordance with the present embodiment, the temperatures of the heaters 400 and 410 are feedback controlled by the controller 700. For this feedback control, the QCMs 310 and 300 are installed for each crucible of the vapor deposition source 210.

In the evaporating apparatus 10 in accordance with the present embodiment, the vapor deposition source 210 and the blowing device 110 are incorporated in the separate chambers. Therefore, the controller 700 detects the vaporization rate of each of the various film forming materials stored in the plurality of crucibles based on vibration numbers (frequencies f1 to f3) of the quartz vibrator outputted from the QCM 310 installed to correspond to each vapor deposition source 210. The controller 700 feedback controls the temperature of each vapor deposition source 210 with high accuracy, based on the vaporization rates thus obtained. In this way, by allowing the vaporization rates of the film forming materials stored in the plurality of vapor deposition source 210 to become approximate to target values more accurately, the amount and the mixture ratio of the mixture of gas molecules blown out from the blowing device 210 can be controlled more accurately. As a result, the controllability of the film formation can be increased, and uniform thin films having fine qualities can be formed on the substrate G.

Furthermore, in the evaporating apparatus 10 in accordance with the present embodiment, the QCM 300 is installed to correspond to the blowing device 110, and the controller 700 calculates the film forming rate of the mixture of gas molecules blown out from the blowing device 110 based on the quartz vibrator's vibration number (frequency ft) outputted from the QCM 300.

In the above-stated way, the controller 700 calculates the vaporization rates of the film forming materials accommodated in each vapor deposition source 210 and the resultant generation rate of the mixture of gas molecules passing through the blowing device 110. As a result, it is possible to detect the loss amount of gas molecules due to their adherence to the connection pipe 220 or the like while they are travelling from the vapor deposition source 210 to the blowing device 110 through the connection pipe 220 or the like. With this configuration, by controlling the temperature of each vapor deposition source 210 more accurately based on the vaporization rate of the gas molecules of the various film forming materials (simple substances) and the generation rate of the mixture of the gas molecules, more uniform thin films having better qualities can be formed on the target object. Further, though it is desirable to install the QCM 300, it is not indispensable.

(Orifice)

As mentioned above, the orifices 240e2 and 240e3 are inserted in the second and third connection pipes 220e2 and 220e3, respectively. In this way, it may be possible to install an orifice at one position adjacent to the junction portion C on any connection pipe 200 connected with the vapor deposition source based on molecule amounts of the various film forming materials vaporized from the plurality of vapor deposition sources per unit time.

For example, assume that a material A, a material B and Alg₃ are used as film forming materials for the fifth layer, as illustrated in FIG. 4. Further, assume that the molecule amount of the material A vaporized from the first crucible 210e1 per unit time is larger than the molecule amounts of the material B and the Alg₃ (aluminum-tris-8-hydroxyquinoline) vaporized from the second and third crucibles 210e2 and 210e3 per unit time, respectively.

In such case, an internal pressure of the connection path 220e1 through which the material A flows becomes higher than internal pressures of the connection paths 220e2 and 220e3 through which the material B and the Alg₃ flow. Accordingly, in case that the connection paths 220e have the same diameters, the gas molecules tend to be introduced from the connection path 220e1 having the higher internal pressure into the connection paths 220e2 and 220e3 having the lower internal pressures via the junction portion C.

Since, however, flow paths of the second and third connection pipes 220e2 and 220e3 are narrowed by the orifices 240e2 and 240e3, respectively, a passage of the gas molecules of the material A is restricted. Accordingly, an inflow of the material A toward the connection paths 220e2 and 220e3 can be suppressed. In this way, by introducing the gas molecules of the film forming materials toward the blowing device 110 while preventing their backflow, a greater amount of gas molecules can be deposited on the substrate G, so that the utilization efficiency of material can be further improved.

As stated, based on the molecule amounts of the various film forming materials vaporized from the plurality of vapor deposition sources (crucibles) per unit time, it is desirable to install the orifices at the connection pipe 220e through which the film forming material having the smaller vaporized amounts flows).

However, it may be also possible not to install any orifice 240e regardless of the amounts of the film forming materials per unit time, or it may be also possible to install one orifice at one of the three connection pipes 220e1 to 220e3. Further, though the orifice 240e can be installed at any position adjacent to the junction position C of the connection pipes 220e1 to 220e3, it is desirable to install it closer to the junction position C than to the vicinity of each crucible 210e in order to prevent the backflow of the vaporized film forming material into the vapor deposition source 210e.

Further, in the evaporating apparatus 10 in accordance with the present embodiment, the orifices 110e15, 210e13, 210e23 and 210e33 are installed at the exhaust paths 110e14, 210e12, 210e22 and 210e32 for exhausting a part of each film forming material, provided on the side of the QCM 300 and the QCM 310.

With this configuration, by restricting the amount of gas molecules passing through each exhaust path by using each orifice, the amount of exhausted gas molecules can be reduced. As a consequence, the unnecessary exhaust of the gas molecules of the film forming materials can be suppressed, so that the utilization efficiency of material can be further enhanced.

Further, the orifices 240e2, 240e3, 110e15, 210e13, 210e23 and 21e33 are an example of a flow path adjusting member for adjusting the flow paths of the connection pipes or the exhaust paths. Another example of the flow path adjusting member may be a variable opening valve for adjusting a flow path of a pipe by varying an opening degree of a valve.

(Modification Example)

Now, a modification example of the 6-layer consecutive film forming process using the evaporating apparatus in accordance with the first embodiment of the present invention will be explained with reference to FIG. 6. In this modification example, a coolant supply source 800 shown in FIG. 6 is provided instead of the power supply 600 installed outside the evaporating apparatus 10 as shown in FIG. 2. Further, as a temperature control mechanism, coolant supply paths 810 shown in FIG. 6 are buried in the wall surface of a second processing chamber 200 in lieu of the heaters 400 and 410 in FIG. 2. The coolant supply source 800 supplies and circulates a coolant through the coolant supply paths 810. With this configuration, a vapor deposition source 210's film forming material accommodating portion can be cooled.

(Maintenance)

During the film formation, the temperature of a vapor deposition source 210 increases up to a high temperature level of about 200 to 500° C. Thus, in order to supplement a film forming material, the vapor deposition source 210 needs to be cooled first to a preset temperature. However, about half a day has been taken to cool the conventional vapor deposition source 210 down to the preset temperature. In this modification example, however, the vapor deposition source 210 is cooled by using the coolant supply source 800 and the coolant supply paths 810. As a result, maintenance time necessary for the supplement of the film forming material can be shortened.

Furthermore, the coolant supply source 800 and the coolant supply paths 810 are an example of a third temperature control mechanism. As another example using the third temperature control mechanism, there can be adopted a method of cooling the film forming material accommodating portion by directly blowing out the coolant such as air supplied from the coolant supply source 800 toward the vicinity of the film forming material accommodating portion. Further, though the coolant can be water, since the temperature of the vapor deposition source 210 is high, it is desirable to use the air as the coolant in consideration of a rapid expansion change.

In the above-described embodiment of the present invention, the size of the glass substrate capable of being processed by the evaporating apparatus 10 is about 730 mm×920 mm or greater. For example, the evaporating apparatus is capable of consecutively carrying out the film formation on G4.5 substrates having a size of about 730 mm×920 mm (in-chamber size: about 1000 mm×1190 mm) or G5 substrates having a size of about 1100 mm×1300 mm (in-chamber size: about 1470 mm×1590 mm). Further, the evaporating apparatus 10 is also capable of carrying out the film formation on a wafer having a diameter of, e.g., about 200 mm or 300 mm. That is, a target object on which the film formation is performed includes a glass substrate and a silicon wafer.

Further, as another example of the first and second sensors used in the feedback control in each embodiment, there can be employed an interferometer (e.g., a laser interferometer) for detecting a film thickness of a target object by, e.g., irradiating light outputted from a light source onto a top surface and a bottom surface of a film formed on the target object and observing and analyzing an interference fringe generated by a difference in optical paths of the two reflected beams.

In the above-described embodiment, the operations of the respective components are interrelated and can be substituted with a series of operations in consideration of such interrelation. By the substitution, the embodiment of the evaporating apparatus can be used as an embodiment of a method of using the evaporating apparatus, and the embodiment of the control apparatus of the evaporating apparatus can be used as an embodiment of a control method for the evaporating apparatus.

Further, by substituting the operation of each component with the process of each component, the embodiment of the control method of the evaporating apparatus can be used as an embodiment of a program for controlling the evaporating apparatus and an embodiment of a computer readable storage medium storing the program therein.

The above description of the present invention is provided for the purpose of illustration, and it would be understood by those skilled in the art that various changes and modifications may be made without changing technical conception and essential features of the present invention. It shall be understood that all modifications and embodiments conceived from the meaning and scope of the claims and their equivalents are included in the scope of the present invention.

For example, in the evaporating apparatus 10 in accordance with the above-described embodiment, an organic EL material in the form of powder (solid) is used as the film forming material, and an organic EL multi-layer film forming process is performed on the substrate G. However, the evaporating apparatus in accordance with the present invention can also be employed in a MOCVD (Metal Organic Chemical Vapor Deposition) method for depositing a thin film on a target object by decomposing a film forming material vaporized from, e.g., a liquid organic metal on the target object heated up to about 500 to 700° C. As described, the evaporating apparatus in accordance with the present invention may be used as an apparatus for forming an organic EL film or an organic metal film on the target object by vapor deposition by using an organic EL film forming material or an organic metal film forming material as a source material.

1. An evaporating apparatus for performing a film formation on a target object by vapor deposition, the apparatus comprising:
a vapor deposition source for vaporizing a film forming material which is a source material for the film formation;
a blowing mechanism connected with the vapor deposition source through a connection path, for blowing out the film forming material vaporized from the vapor deposition source;
a first processing chamber accommodating the blowing mechanism therein, for performing therein the film formation on the target object with the film forming material blown out from the blowing mechanism;
a second processing chamber installed separately from the first processing chamber, for accommodating the vapor deposition source therein; and
an exhaust mechanism connected with the first processing chamber and the second processing chamber, for evacuating the inside of the first processing chamber and the second processing chamber to a preset vacuum level,
wherein the vapor deposition source includes a temperature control mechanism for controlling a temperature of the vapor deposition source, and
the film forming material vaporized from the vapor deposition source is carried from the vapor deposition source to the blowing mechanism via the connection path by using a nonreactive gas as a carrier gas.

2. (canceled)

3. The evaporating apparatus of claim 1, wherein the vapor deposition source is installed such that only the vicinity of its film forming material accommodating portion is in contact with a wall surface of the second processing chamber.

4. The evaporating apparatus of claim 3, wherein the second processing chamber is provided with at least one of a prominent portion and a recess portion in the wall surface in contact with the vapor deposition source.

5. (canceled)

6. The evaporating apparatus of claim 1, wherein the temperature control mechanism includes a first temperature control mechanism and a second temperature control mechanism,
the first temperature control mechanism is disposed on the side of the film forming material accommodating portion of the vapor deposition source, so as to maintain a temperature of the film forming material accommodating portion to a predetermined temperature, and
the second temperature control mechanism is disposed at a vapor deposition source's outlet portion, from which the film forming material is discharged, so as to maintain a temperature of the outlet portion to be higher than or equal to the temperature of the film forming material accommodating portion.

7. The evaporating apparatus of claim 1, wherein the temperature control mechanism includes a third temperature control mechanism, and
the third temperature control mechanism is disposed in the vicinity of the film forming material accommodating portion of the vapor deposition source so as to cool the film forming material accommodating portion.

8. The evaporating apparatus of claim 1, wherein more than one said vapor deposition source is installed, and
a plurality of first sensors corresponding to the vapor deposition sources is disposed in the inside of the second processing chamber to detect respective vaporization rates of film forming materials accommodated in the vapor deposition sources.

9. The evaporating apparatus of claim 8, wherein a second sensor corresponding to the blowing mechanism is disposed in the inside of the first processing chamber to detect a film forming rate of the film forming material blown out from the blowing mechanism.

10. The evaporating apparatus of claim 1, wherein more than one said vapor deposition source is installed; different kinds of film forming materials are accommodated in the vapor deposition sources, respectively; connection paths respectively connected with the vapor deposition sources are coupled at a preset junction position; and based on the amounts of the different kinds of film forming materials vaporized from the vapor deposition sources per unit time, a flow path adjusting member is installed at one of the connection paths upstream of the preset junction position to control a flow path of said one connection path.

11. The evaporating apparatus of claim 10, wherein based on the amounts of the different kinds of film forming materials vaporized from the vapor deposition sources per unit time, the flow path adjusting member is installed at the connection path through which the film forming material having a low vaporization rate per unit time passes.

12. The evaporating apparatus of claim 9, wherein the flow path adjusting member is installed at one of exhaust paths for exhausting a part of each vaporized film forming material toward the first sensors and the second sensor to control a flow path of said one exhaust path.

13. The evaporating apparatus of claim 1, wherein more than one said blowing mechanism is installed, and
the first processing chamber accommodates the blowing mechanisms therein, and a plurality of film forming processes is consecutively performed on the target object with the film forming material blown out from each blowing mechanism in the first processing chamber.

14. The evaporating apparatus of claim 1, wherein the first processing chamber forms an organic EL film or an organic metal film on the target object by vapor deposition by using an organic EL film forming material or an organic metal film forming material as a source material.

15. A control apparatus for controlling the evaporating apparatus as claimed in claim 8, wherein the control apparatus feedback controls a temperature of a temperature control mechanism installed at each vapor deposition source based on the respective vaporization rates of the film forming materials detected by the first sensors.

16. A control apparatus for controlling the evaporating apparatus as claimed in claim 9, wherein the control apparatus feedback controls a temperature of a temperature control mechanism installed at each vapor deposition source based on the respective vaporization rates of the film forming materials detected by the first sensors and the film forming rate of the film forming material detected by the second sensor.

17. The control apparatus of claim 15, wherein the temperature of the temperature control mechanism installed at each vapor deposition source is feedback controlled such that a temperature of a vapor deposition source's outlet portion from which the film forming material is discharged is set to be higher than or equal to a temperature of a film forming material accommodating portion of the vapor deposition source.

18. A control method for controlling the evaporating apparatus as claimed in claim 8, wherein a temperature of a temperature control mechanism installed at each vapor deposition source is feedback controlled based on the respective vaporization rates of film forming materials detected by the first sensors.

19. A control method for controlling the evaporating apparatus as claimed in claim 9, wherein a temperature of a temperature control mechanism installed at each vapor deposition source is feedback controlled based on the respective vaporization rates of the film forming materials detected by the first sensors and the film forming rate of the film forming material detected by the second sensor.

20. A method for using the evaporating apparatus as claimed in claim 1, the method comprising:
vaporizing the film forming material accommodated in the vapor deposition source in the inside of the second processing chamber evacuated to a preset vacuum level;
carrying the vaporized film forming material from the vapor deposition source to the blowing mechanism through the connection path by using a nonreactive gas as a carrier gas while a temperature of the vapor deposition source is controlled by a temperature control mechanism installed at the vapor deposition source;
blowing out the vaporized film forming material from the blowing mechanism; and
performing the film formation on the target object with the blown film forming material in the inside of the first processing chamber evacuated to a preset vacuum level.
